(19) United States
(12) Patent Application Publication
(10) Pub. No.: US 2020/0102476 A1
(43) Pub. Date: Apr. 2, 2020

(54) Barrier Slurry Removal Rate Improvement

(71) Applicant: Versum Materials US, LLC, Tempe, AZ (US)

(72) Inventors: Lu Gan, Phoenix, AZ (US); James Allen Schlueter, Phoenix, AZ (US)

(73) Assignee: Versum Materials US, LLC, Tempe, AZ (US)

(21) Appl. No.: 16/577,580

(22) Filed: Sep. 20, 2019

Related U.S. Application Data
(60) Provisional application No. 62/738,427, filed on Sep. 28, 2018.

(51) Int. Cl. C09G 1/02; H01L 21/321; H01L 21/768

(52) U.S. Cl. CPC C09G 1/02; H01L 21/7684; H01L 21/3212

(57) ABSTRACT

Present invention provides Chemical Mechanical Planarization Polishing (CMP) compositions for barrier layer and interlayer dielectric (ILD) structure or patterned dielectric layer applications. The CMP compositions contain abrasive, chemical additive comprising polyprotic acid and its salt; corrosion inhibitor; and water soluble solvent; and optionally; second rate booster; a surfactant; pH adjusting agent; oxidizing agent; and chelator.

### CROSS-REFERENCE TO RELATED APPLICATIONS

This patent application is a non-provisional of U.S. provisional patent application Ser. No. 62/738,427 filed on Sep. 28, 2018, which is incorporated herein by reference in its entirety.

### BACKGROUND OF THE INVENTION

The present invention relates to barrier chemical mechanical planarization (“CMP”) polishing composition (or slurry) used in the production of a semiconductor device, and polishing methods for carrying out chemical mechanical planarization. In particular, it relates to barrier polishing compositions that are suitably used for polishing patterned semiconductor wafers that are composed of multi-type films, for instances, metal layer, a barrier film, and an underlying interlayer dielectric (ILD) structure or patterned dielectric layer.

Usually, a barrier layer covers the patterned dielectric layer and a metal layer covers the barrier layer. The metal layer has at least sufficient thickness to fill the patterned trenches with metal to form circuit interconnects.

A barrier typically is a metal, metal alloy or intermetallic compound, examples are Ta or Ti containing film, such as Ta, TaN, Ti, TiN, or TiW, or et al. The barrier forms a layer that prevents migration or diffusion between layers within a wafer. For example, barriers prevent the diffusion of interconnect metal such as copper or cobalt into an adjacent dielectric. Barrier materials must be resistant to corrosion by most acids, and thereby, resist dissolution in a fluid polishing composition for CMP. Furthermore, these barrier materials may exhibit a toughness that resists removal by abrasion abrasive particles in a CMP composition and from fixed abrasive pads.

In relation to CMP, the current state of this technology involves the use of a multi-step such as, for example, a two-step process to achieve local and global planarization.

During step one of a typical CMP process, a metal layer such as an overburdened copper layer is typically removed, while leaving a smooth planar surface on the wafer with metal-filled lines, vias and trenches that provide circuit interconnects planar to the polished surface. Thus, Step 1 tends to remove excess interconnect metals, such as copper. Then step two of a typical CMP process, frequently referred to as a barrier CMP process, follows to remove the excess metal layers and the barrier layer and other films on the surface of the patterned wafers to achieve both local and global planarization of the surface on the dielectric layer.

U.S. Pat. No. 7,491,252 B2 discloses a chemical mechanical planarization solution for removing tantalum barrier materials. The solution includes nonferrous metal and 0 to 20 complexing agent for the non-ferrous metal, 0.01 to 12 tantalum removal agent selected from the group consisting of formamidine, formamidine salts, formamidine derivatives, guanidine derivatives, guanidine salts and mixtures thereof, 0 to 5 abrasive, 0 to 15 total particles selected from the group consisting of polymeric particles and polymer-coated coated particles and balance water. The solution has a tantalum nitride to TEOS selectivity of at least 3 to 1 measured with a microporous polyurethane polishing pad pressure measure normal to wafer less than 20.7 KPa.

Chemical mechanical planarization (CMP) of the barrier layer is a critical step wafer damascene process.

Therefore, there is a need to make CMP slurries with higher removal rate.

### BRIEF SUMMARY OF THE INVENTION

The present invention provides stable CMP slurries with higher Barrier and ILD removal rates. Described and disclosed herein are barrier CMP compositions, systems and methods for polishing. The compositions disclosed herein provide improved, high barrier film and ILD layer removal rates.

In one embodiment, described herein is a barrier chemical mechanical planarization polishing composition comprising:
≥1.5 wt. %, ≥2.4 wt. %, ≥5.0 wt. %, or ≥10. wt. % of abrasive;
≤10 wt. %, preferably ≤5 wt. %; more preferably ≤1 wt. % of chemical additive;
corrosion inhibitor;
water soluble solvent;
optionally
second rate booster;
surfactant;
pH adjusting agent;
oxidizing agent; and
chelator;
wherein
the chemical additive comprises at least one polyprotic acid or its salt having more than one Pka and having a Pka1 from 0 to 12, 0.5 to 10, 1 to 7, or 1 to 3;
the second rate booster has its molecular molar conductivity ≥75 S·cm²/mol in aqueous solution at 25° C.; and
the polishing composition has a pH from 2 to 12, 3 to 12, 4 to 12, 6 to 11, or 7 to 11.

In another aspect, the present invention provides a polishing method for chemical mechanical planarization of a semiconductor device comprising at least one surface having at least a barrier layer and a dielectric layer; the method comprising the steps of:

a. contacting the at least one surface with a polishing pad;
b. delivering to the at least one surface the polishing composition as described herein, and
c. polishing the at least one surface with the polishing composition;
wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof.

In yet another aspect, the present invention provides a system for chemical mechanical planarization, comprising:

a semiconductor device comprising at least one surface having at least a barrier layer and a dielectric layer;
a polishing pad; and
a polishing composition as described herein;
wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, silane oxide film, low-K material, and combinations thereof; and
the at least one surface is in contact with the polishing pad and the polishing composition.

Example of the abrasive includes but is not limited to colloidal silica, alumina, ceria, germania, silica, titania, zirconia, alumina dopes colloidal silica in lattices, organic polymer particles, composite particles of inorganic and organic particles (such as ceria coated silicon particles), surface modified inorganic/organic particles, and combinations thereof.

The chemical additive includes but is not limited to polyprotic acid and its salt, diprotic acid, its derivatives and their salts; triprotic acid, its derivatives and their salts; and combinations thereof.

A polyprotic acid is an acid that can donate more than one proton or hydrogen atom per molecule to an aqueous solution during dissociation. A diprotic acid is an acid that can donate two proton or hydrogen atoms, and a triprotic acid is an acid that can donate three proton or hydrogen atoms. A diprotic acid and a triprotic acid are polyprotic acids.

The chemical additive comprises at least one polyprotic acid or its salt that has more than one Pka and has its Pka1 is, but not limited to, 0 to 12, 0.5 to 10, 1 to 7, or 1 to 3. Pka1 is the negative logs of the acidity constant for the first stage in which a a polyprotic acid loses a proton or hydrogen atom.

More specifically, examples of the chemical additive includes but is not limited to the group selected from the group consisting of phosphonoacetic acid, its derivatives and their salts; phosphonic acid, its derivatives and their salts; phenylphosphonic acid, its derivatives and their salts; molybdenum diacid, it derivatives and their salts; oxalic acid, its derivatives and their salts; sulfurous acid, its derivative and their salts; arsenic acid, its derivatives and their salts; nitrobenzoic acid, its derivative and their salts; malonic acid, its derivative and their salts; phthalic acid, its derivative and their salts; silicic acid, its derivative and their salts; carbonic acid, its derivative and their salts; and combinations thereof.

The chemical additive is used in an amount ranging from about 0.001 wt. % to about 10 wt. %; from about 0.01 wt. % to about 5 wt. %; from about 0.025 wt. % to about 3 wt. %, or from about 0.05 wt. % to about 1 wt. %.

Example of the water-soluble solvent includes but is not limited to DI water, a polar solvent and a mixture of DI water and polar solvent. The polar solvent can be any alcohol, ether, ketone, or other polar reagent. Examples of polar solvents include alcohols, such as isopropyl alcohol, ethers, such as tetrahydrofuran and diethyl ether, and ketones, such as acetone.

Example of the corrosion inhibitor includes but is not limited to benzotriazole or benzotriazole derivatives, 3-amino-1, 2, 4-triazole, 3, 5-diamine-1, 2, 4-triazole, and combinations thereof; and in an amount ranging from 0.001 wt. % to 1.0 wt. %; 0.0025 wt. % to 0.75 wt. %; 0.005 wt. % to 0.5 wt. %; 0.0075 wt. % to 0.25 wt. %; or 0.01 wt. % to 0.1 wt. %.

Example of the surfactant includes but is not limited to a). non-ionic surface wetting agents; b). anionic surface wetting agents; c). cationic surface wetting agents; d). ampholytic surface wetting agents; and combinations thereof and in an amount ranging from about 0.0 wt. % to about 10 wt. %; 0.0005 wt. % to about 5 wt. %; 0.001 wt. % to about 1.0 wt. %; or 0.005 to 0.25 wt. %.

More specifically, examples of surfactants include, but are not limited to, dodecyl sulfate sodium salt, sodium lauryl sulfate, dodecyl sulfate ammonium salt, secondary alkane sulfonates, alcohol ethoxylate, acetylenic surfactant, and any combination thereof.

Example of the pH adjusting agent includes but is not limited to (a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and in an amount ranging from about 0 wt. % to 3 wt. %; preferably 0.001 wt. % to 1 wt. %; more preferably 0.01 wt. % to 0.5 wt. % pH adjusting agent.

The polishing composition has a pH from 2 to 12, 3 to 12, 4 to 12, 6 to 11, or 7 to 11.

Example of the second rate booster agent includes but is not limited to an organic acid or its salt; inorganic salt where its molar conductivities in aqueous solutions at 25° C. is 75 S·cm²/mol, and in an amount ranging from about 0.0 wt. % to about 10 wt. %; about 0.001 wt. % to about 7 wt. %; about 0.05 wt. % to about 5 wt. %; preferably from about 0.01 wt. % to about 3 wt. %.

Example of the second rate booster agent includes but is not limited to nitrate salt (potassium, sodium, ammonium, lithium, piperidinium, their derivatives), nitric salt (potassium, sodium, ammonium, lithium, piperidinium, their derivatives), chloride salt (potassium, sodium, ammonium, lithium, piperidinium, their derivatives), acetate salt (potassium, sodium, ammonium, lithium, piperidinium, their derivatives), and combinations thereof

Example of the oxidizing agent includes but is not limited to hydrogen peroxide, periodic acid, potassium iodate, potassium permanganate, ammonium persulfate, ammonium molybdate, ferric nitrate, nitric acid, potassium nitrate, ammonia, amine compounds, and combinations thereof; and in an amount ranging from about 0.0 wt. % to about 10 wt. %; 0.01 wt. % to 7 wt. %; 0.05 wt. % to 5 wt. %; or from about 0.1 wt. % to about 2 wt. %.

Suitable chelator includes but is not limited to organic acids and their salts; polymeric acids and their salts; water-soluble copolymers and their salts; copolymers and their salts containing at least two different types of acid groups selected from carboxylic acid groups; sulfonic acid groups; phosphoric acids; and pyridine acids in the same molecule of a copolymer; polyvinyl acids and their salts; polyethylene oxide; polypropylene oxide; pyridine, pyridine derivatives, bipyridine, bipyridine derivatives, and combinations thereof.

Example of the chelator includes but is not limited to potassium citrate, benzosulfonic acid, 4-tolyl sulfonic acid, 2,4-diamino-benzosulfonic acid, and malonic acid, itaconic acid, malic acid, tartaric acid, citric acid, oxalic acid, gluconic acid, lactic acid, mandelic acid, amino acids, polycarboxy amino acids, phosphonic acids, salts thereof, and combinations thereof.

The chelator is used in an amount ranging from about 0.0 wt. % to about 10 wt. %; from about 0.01 wt. % to about 10 wt. %; from about 0.05 wt. % to about 5 wt. %; or preferably 0.01 wt. % to 1.0 wt. %.

### BRIEF DESCRIPTION OF SEVERAL VIEWS OF THE DRAWINGS

FIG. 1 Removal Rate comparison between Slurry A (containing no chemical additive) and Slurry B (containing the chemical additive)

FIG. 2 Removal Rate comparison between Slurry C (containing no chemical additive) and Slurry D (containing the chemical additive)

FIG. 3 Removal Rate comparison between Slurry E (containing no chemical additive) and Slurry F (containing the chemical additive)

FIG. 4 Removal Rate comparison between slurry G POU (point of use) (containing no chemical additive) and Slurry H POU (containing the chemical additive)

FIG. 5 Removal Rate comparison between slurry I POU (containing no chemical additive) and Slurry J POU (containing the chemical additive)

FIG. 6 Removal Rate comparison between Slurry E (containing no chemical additive) and Slurry K (containing the chemical additive)

FIG. 7 Removal Rate comparison between slurry I POU (containing no chemical additive) and Slurry L POU (containing the chemical additive)

FIG. 8 Removal Rate comparison between slurry M POU (containing no chemical additive) and Slurry N POU (containing the chemical additive)

### DETAILED DESCRIPTION OF THE INVENTION

Described herein are stable CMP slurries polishing a semiconductor substrate or device having a conductive metal layer, an underlying barrier film, and a dielectric layer having imbedded metal interconnect structures.

The present invention provides stable CMP slurries with higher Barrier and ILD removal rates. Described and disclosed herein are barrier CMP compositions, systems and methods for polishing. The compositions disclosed herein boost the barrier film ad ILD removal rates.

The conductive metal layer comprises such as Cu, CuMn, Co, CoMo, Al, AlCo, Ru, RuTa, RuTiN, Mn, and combinations thereof. The barrier or liner layer comprises tantalum or titanium containing films selected from the group consisting of Ta, TaN, Ti, TiN, TiW or TiWN, and combinations thereof. The underlying interlayer dielectric (ILD) layer comprises silicon dioxide film such as SiO2, TEOS; low-K dielectric material; and combinations thereof.

The barrier chemical mechanical planarization polishing composition comprises:
≥1.5 wt. %, ≥2.4 wt. %, ≥5.0 wt. %, ≥10. wt. % of abrasive;
≤10 wt. %, preferably ≤5 wt. %; more preferably ≤1 wt. % of chemical additive;
corrosion inhibitor,
water soluble solvent;
optionally
second rate booster
surfactant;
pH adjusting agent;
oxidizing agent; and
chelator; wherein
the chemical additive comprises at least one polyprotic acid or its salt having more than one Pka and having a Pka1 from 0 to 12, 0.5 to 10, 1 to 7, or 1 to 3;
the second rate booster has its molecular molar conductivity ≥75 S·cm²/mol in aqueous solution at 25° C.; and
the polishing composition has a pH of 2 to 12, 3 to 12, 4 to 12, 6 to 11, or 7 to 11.

The polishing compositions of the present invention comprise an abrasive. Suitable abrasives for polishing compositions are nano-sized particles include, but are not limited to, nano-sized colloidal silica or high purity colloidal silica particles; nano-sized inorganic metal oxide particles, such as alumina, titania, zirconia, ceria, and combinations thereof; nano-sized diamond particles; nano-sized silicon nitride particles; mono-modal, bi-modal, or multi-modal colloidal abrasive particles; organic polymer-based soft abrasives; surface-coated or modified abrasives; and combinations thereof.

The surface-coated or modified abrasives include but are not limited to the colloidal silica particles doped by other metal oxide within lattice of the colloidal silica, such as alumina doped silica particles, colloidal aluminum oxide, which include alpha-, beta-, and gamma-types of aluminum oxides, colloidal and photoactive titanium dioxide, cerium oxide, colloidal cerium oxide, nano-sized diamond particles, nano-sized silicon nitride particles, mono-modal, bi-modal, multi-modal colloidal abrasive particles, zirconium oxide, organic polymer-based soft abrasives, surface-coated or modified abrasives, and mixtures thereof.

The nano-sized particles have narrow or broad particle size distributions, various sizes and various shapes. The various shapes of the abrasives include spherical shape, cocoon shape, aggregate shape and other shapes.

The abrasive particles may be purified using a suitable method such as ion exchange to remove metal impurities that may help improve the colloidal stability. Alternatively, high purity silica abrasive particles that are manufactured from precursors other than metal silicates can be used.

Preferred abrasives include, but are not limited to, high purity colloidal silica, alumina, ceria, germania, silica, titania, zirconia, alumina dopes colloidal silica in lattices, and mixtures thereof. Colloidal silica is a most preferred abrasive particle.

The silica can be any of precipitated silica, fumed silica, silica fumed, pyrogenic silica, silica doped with one or more adjutants, or any other silica-based compound. In an alternate embodiment, the silica can be produced, for example, by a process selected from the group consisting of a sol-gel process, a hydrothermal process, a plasma process, a fuming process, a precipitation process, and any combination thereof.

It is preferred that the mean particle size of the abrasive as measured by Disc Centrifuge (DC) particle sizing method is between 10 nm and 300 nm, or more preferably between 15 nm and 200 nm, and even more preferably between 25 nm and 90 nm.

In general, the above-mentioned abrasive particles may be used either alone or in combination with one another. Two or more abrasive particles with different sizes may also be combined to obtain excellent performance.

Typically, the abrasive is present in the compositions of the present invention in an amount ranging from ≥1.5 wt. %, ≥2.4 wt. %, ≥5.0 wt. %, ≥10. wt. % relative to the total weight of the CMP composition.

Example of the water-soluble solvent includes but is not limited to DI water, a polar solvent and a mixture of DI water and polar solvent. The polar solvent can be any alcohol, ether, ketone, or other polar reagent. Examples of polar solvents include alcohols, such as isopropyl alcohol, ethers, such as tetrahydrofuran and diethyl ether, and ketones, such as acetone.

The chemical additive includes but is not limited to diprotic acid, its derivatives and their salts; triprotic acid, its derivatives and their salts; polyprotic acid and its salt, and combinations thereof. The chemical additive has PKa1 from 0 to 12, 0.5 to 10, 1 to 7, or 1 to 3.

The chemical additives are used as the first rate booster.

More specifically, examples of the chemical additive includes but is not limited to the group selected from the group consisting of phosphonoacetic acid, its derivatives and their salts; phosphonic acid, its derivatives and their salts; phenylphosphonic acid, its derivatives and their salts; molybdenum diacid, it derivatives and their salts; oxalic acid, its derivatives and their salts; sulfurous acid, its derivative and their salts; arsenic acid, its derivatives and their salts; nitrobenzoic acid, its derivative and their salts; malonic acid, its derivative and their salts; phthalic acid, its derivative and their salts; silicic acid, its derivative and their salts; carbonic acid, its derivative and their salts; and combinations thereof.

The chemical additive is used in an amount ranging from about 0.001 wt. % to about 10 wt. %; preferably from about 0.01 wt. % to about 5 wt. %; from about 0.025 wt. % to about 4 wt. %, or from about 0.05 wt. % to about 1 wt. %.

A surfactant is used in the barrier CMP slurry as surface wetting agent; suitable surfactant compounds that may be added to the barrier CMP slurry as surface wetting agent include, any of the numerous nonionic, anionic, cationic or amphoteric surfactants known to those skilled in the arts. One example of the nonionic surfactant is tricosaethylene glycol dodecyl ether.

Examples of surfactants also include, but are not limited to, dodecyl sulfate sodium salt, sodium lauryl sulfate, dodecyl sulfate ammonium salt, secondary alkane sulfonates, alcohol ethoxylate, acetylenic surfactant, and any combination thereof.

Examples of suitable commercially available surfactants include TRITON™, Tergitol™, DOWFAX™ family of surfactants manufactured by Dow Chemicals and various surfactants in SURFYNOL™, DYNOL™, Zetasperse™, Nonidet™, and Tomadol™ surfactant families, manufactured by Air Products and Chemicals.

Suitable surfactants of surfactants may also include polymers comprising ethylene oxide (EO) and propylene oxide (PO) groups. An example of EO-PO polymer is Tetronic™ 90 R4 from BASF Chemicals.

When employed, the amount of surfactant typically ranges from 0.0001 wt. % to about 1.0 wt. % relative to the total weight of the barrier CMP composition. When employed, the range is 0.0 wt. % to about 10 wt. %; 0.0005 wt. % to about 5 wt. %; 0.001 wt. % to about 1 wt. %; or 0.005 to 0.25 wt. %.

Example of the corrosion inhibitor includes but is not limited to benzotriazole or benzotriazole derivatives, 3-amino-1, 2, 4-triazole, 3, 5-diamine-1, 2, 4-triazole, and combinations thereof.

The corrosion inhibitor is used in an amount ranging from 0.001 wt. % to 1.0 wt. %; 0.0025 wt. % to 0.75 wt. %; 0.005 wt. % to 0.5 wt. %; 0.0075 wt. % to 0.25 wt. %; or 0.01 wt. % to 0.1 wt. %.

Example of the pH adjusting agent includes but is not limited to (a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and is used in an amount ranging from about 0.0001 wt. % to about 3 wt. %; and the polishing composition has a pH from about 2 to 12, 3 to 12, 4 to 12, 6 to 11, or 7 to 11.

Example of the second rate booster agent includes but is not limited to an organic acid or its salt; inorganic salt where its molar conductivities in aqueous solutions at 25° C. is 75 S·cm²/mol, and in an amount ranging from about 0.0 wt. % to about 10 wt. %; about 0.001 wt. % to about 7 wt. %; about 0.005 wt. % to about 5 wt. %, or from about 0.01 wt. % to about 3 wt. %.

Example of the second rate booster agent includes but is not limited to nitrate salt (potassium, sodium, ammonium, lithium, piperidinium, their derivatives), nitric salt (potassium, sodium, ammonium, lithium, piperidinium, their derivatives), chloride salt (potassium, sodium, ammonium, lithium, piperidinium, their derivatives), acetate salt (potassium, sodium, ammonium, lithium, piperidinium, their derivatives), and combinations thereof.

Example of the oxidizing agent includes but is not limited to hydrogen peroxide, periodic acid, potassium iodate, potassium permanganate, ammonium persulfate, ammonium molybdate, ferric nitrate, nitric acid, potassium nitrate, ammonia, amine compounds, and combinations thereof.

The oxidizing agent is used in an amount ranging from about 0.0 wt. % to about 10 wt. %; 0.01 wt. % to 7 wt. %; 0.05 wt. % to 5 wt. %; or from about 0.1 wt. % to about 2 wt. %.

Suitable chelator includes but is not limited to organic acids and their salts; polymeric acids and their salts; water-soluble copolymers and their salts; copolymers and their salts containing at least two different types of acid groups selected from carboxylic acid groups; sulfonic acid groups; phosphoric acids; and pyridine acids in the same molecule of a copolymer; polyvinyl acids and their salts; polyethylene oxide; polypropylene oxide; pyridine, pyridine derivatives, bipyridine, bipyridine derivatives, and combinations thereof.

Example of the chelator is selected from the group consisting of potassium citrate, benzosulfonic acid, 4-tolyl sulfonic acid, 2,4-diamino-benzosulfonic acid, and malonic acid, itaconic acid, malic acid, tartaric acid, citric acid, oxalic acid, gluconic acid, lactic acid, mandelic acid, amino acids, polycarboxy amino acids, phosphonic acids and combinations thereof and salts thereof.

The chelator is used in an amount ranging from about 0.0 wt. % to about 10 wt. %; preferably from about 0.05 wt. % to about 5 wt. %; and more preferably 0.01 wt. % to 1.0 wt. %.

The present invention also provides a polishing method for chemical mechanical planarization of a semiconductor device comprising at least one surface having at least a barrier layer and a dielectric layer; the method comprising the steps of:

a. contacting the at least one surface with a polishing pad;
b. delivering to the at least one surface the polishing composition as described herein, and
c. polishing the at least one surface with the polishing composition;
wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of silicon dioxide film, low-K material, and combinations thereof.

The present invention further provides a system for chemical mechanical planarization, comprising:

a semiconductor device comprising at least one surface having at least a barrier layer and a dielectric layer;
a polishing pad; and
a polishing composition as described herein;
wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of silicon dioxide film, low-K material, and combinations thereof; and
the at least one surface is in contact with the polishing pad and the polishing composition.

### General Experimental Procedure

In the examples presented below, all percentages are weight percentages unless otherwise indicated. Water is added to make the composition 100 wt. %.

In the examples presented below, CMP experiments were run using the procedures and experimental conditions given below.

The CMP tool that was used in the examples is a Mirra®, manufactured by Applied Materials, 3050 Boweres Avenue, Santa Clara, Calif., 95054. Polishing was performed on VP3500 polisher pad from Dow Chemicals. Polishing was performed at 1.1 psi down force and 93 RPM table speed with 200 ml/min composition flow rates. Polishing experiments were conducted using electroplating deposited copper, plasma enhanced deposition of tetraethoxy silane (TEOS) dielectric, Tantalum (Ta) and Tantalum Nitride (TaN) films. These blanket wafers were purchased from Silicon Valley Microelectronics, 1150 Campbell Ave, Calif., 95126, and Advantiv Corporation. Defects on the wafer films were measured using Surfscan SP2 wafer inspection tool, manufactured by KLA-Tencor, One Technology Drive, Milpitas, Calif. 95035.

Silicon particle about 60 nm (measured by light scattering) purchased from Fuso Chemical Co. LTD, Japan.

### Example 1

The chemical constituents used for the slurry were shown in Table 1. DI Water was added to make the composition 100 wt. %.

The pH of the slurry 7.5-9.

TABLE 1

| Composition | | Slurry A | Slurry B |
|---|---|---|---|
| DI water | Solvent | 94.67 | 94.57 |
| Malonic acid | Chemical additive | | 0.1 |
| Potassium nitrate | Second rate booster | 0.2 | 0.2 |
| Potassium hydroxide | pH adjusting agent | 0.1 | 0.1 |
| Silica Particle | Abrasive | 5 | 5 |
| benzotriazole | Inhibitor | 0.02 | 0.02 |
| Surfactant (surfynol 465) | Surfactant | 0.01 | 0.01 |

The slurries were prepared by adding each chemical constituent shown in Table I continuously at room temperature with a short break (several minutes) apart from each component.

The slurries were used for polishing after 1 wt. % hydrogen peroxide was added to the slurries as an oxidizing agent.

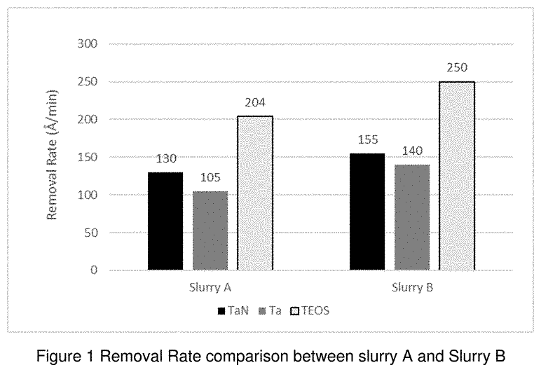

Polishing results for TaN, Ta and TEOS were shown in FIG. 1.

As shown in FIG. 1, both barrier (Ta and TaN) and ILD (TEOS) removal rates were boosted with the addition of malonic acid.

Malonic acid is a polyprotic acid (diprotic) with PKa1 of 2.8 at 20° C.

Potassium nitrate is a second rate booster in which K⁺ has molar ionic conductivity in aqueous solution at 25° C. of 73.5 S·cm²/mol and NO₃⁻ has molar ionic conductivity in aqueous solution at 25° C. of 71.46 S·cm²/mol.

Thus, Example 1 demonstrated that the addition of a polyprotic acid with PKa1 between 1 and 3 can boost both barrier and ILD removal rates

### Example 2

The chemical constituents used for the slurry were shown in Table 1. DI Water was added to make the composition 100 wt. %.

The pH of the slurry 10-10.5.

TABLE 2

| Composition | | Slurry C | Slurry D |
|---|---|---|---|
| DI water | Solvent | 94.41 | 94.21 |
| Potassium sulfite | Chemical additive | | 0.2 |
| Potassium acetate | Second rate booster | 0.4 | 0.4 |
| Potassium hydroxide | pH adjusting agent | 0.17 | 0.17 |
| Silica Particle | Abrasive | 5 | 5 |
| benzotriazole | Inhibitor | 0.01 | 0.01 |
| Surfactant (surfynol 465) | Surfactant | 0.01 | 0.01 |

The slurries were prepared by adding each chemical constituent shown in Table I continuously at room temperature with a short break (several minutes) apart from each component.

The slurries were used for polishing after 1 wt. % hydrogen peroxide was added to the slurries as an oxidizing agent.

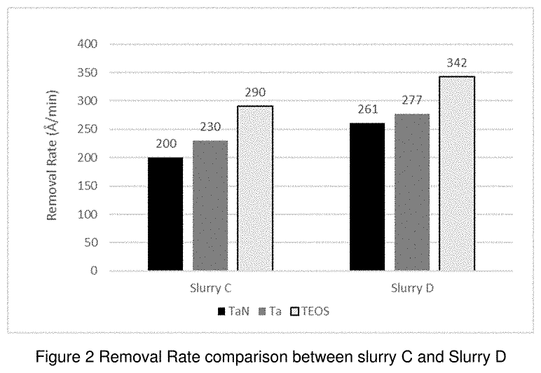

Polishing results for TaN, Ta and TEOS were shown in FIG. 2.

As shown in FIG. 2, both barrier (Ta and TaN) and ILD (TEOS) removal rates were boosted with the addition of potassium sulfite.

Potassium sulfite is a salt of sulfurous acid (diprotic acid) with PKa1 of 1.85 at 20° C.

Potassium acetate is a second rate booster in which K⁺ has molar ionic conductivity in aqueous solution at 25° C. of 73.5 S·cm²/mol and acetate ion has molar ionic conductivity in aqueous solution at 25° C. of 40.9 S·cm²/mol.

Thus, Example 2 demonstrated that the addition of a salt of polyprotic acid with PKa1 between 1 and 3 can boost both barrier and ILD removal rates.

### Example 3

The chemical constituents used for the slurry were shown in Table 3. DI Water was added to make the composition 100 wt. %.

The pH of the slurry was around 7-10.

TABLE 3

| Composition | | Slurry E | Slurry F |
|---|---|---|---|
| DI water | Solvent | 93.97 | 93.37 |
| Potassium molybdate | Chemical additive | | 0.60 |
| Potassium Silicate | Chemical additive | 0 | 1 |
| Silica Particle | Abrasive | 5 | 5 |
| benzotriazole | Inhibitor | 0.0200 | 0.0200 |
| Surfactant (Dynol 607) | Surfactant | 0.01 | 0.01 |

The slurries were prepared by adding each chemical constituent shown in Table 3 continuously at room temperature with a short break (several minutes) apart from each component.

The slurries were used for polishing after 1 wt. % hydrogen peroxide was added to the slurries as an oxidizing agent.

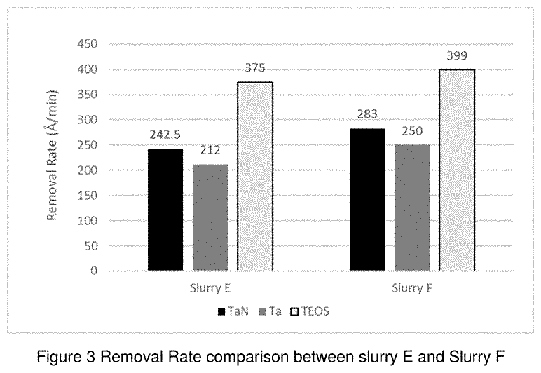

Polishing results for TaN, Ta and TEOS were shown in FIG. 3.

As shown in FIG. 3, both barrier (Ta and TaN) and ILD (TEOS) removal rates were boosted with the addition of both potassium molybdate and potassium silicate.

Potassium molybdate is the salt of molybdenum diacid, and molybdenum diacid is a diprotic acid with PKa1 at 20° C. of 2.9.

Potassium silicate is the salt of silicic acid, and silicic acid is a polyprotic acid with PKa1 at 20° C. of 6-10.

Thus, Example 3 demonstrated that the addition of both a salt of polyprotic acid with PKa1 between 1 and 3 and a salt of polyprotic acid with PKa1 between 0.5 to 10 can boost both barrier and ILD removal rates.

### Example 4

The chemical constituents used for the slurry were shown in Table 4. DI Water was added to make the composition 100 wt. %.

The PH of the slurry is 7.5-8.5.

TABLE 4

| Composition | | Slurry G | Slurry H |
|---|---|---|---|
| DI water | Solvent | 82.14 | 81.84 |
| Phosphonoacetic acid | Chemical additive | | 0.30 |
| Potassium hydroxide | pH adjusting agent | 0.17 | 0.17 |
| Potassium nitrate | Second rate booster | 0.6 | 0.6 |
| Silica Particle | Abrasive | 17 | 17 |
| benzotriazole | Inhibitor | 0.0600 | 0.0600 |
| Surfactant (Dynol 607) | Surfactant | 0.03 | 0.03 |

The slurry was prepared with a normal slurry preparation process, that is, by adding each chemical constituent shown in Table 4 continuously at room temperature with a short break (several minutes) apart from each component.

The slurries at point of use (POU) for polishing after diluting slurries G and H with DI water and adding 1 wt. % hydrogen peroxide as an oxidizing agent, as shown in Table 5.

TABLE 5

| | Slurry G | Slurry H |
|---|---|---|
| | POU | POU |
| DI water | 66 | 66 |
| Slurry G | 33 | |
| Slurry H | | 33 |
| hydrogen peroxide | 1 | 1 |

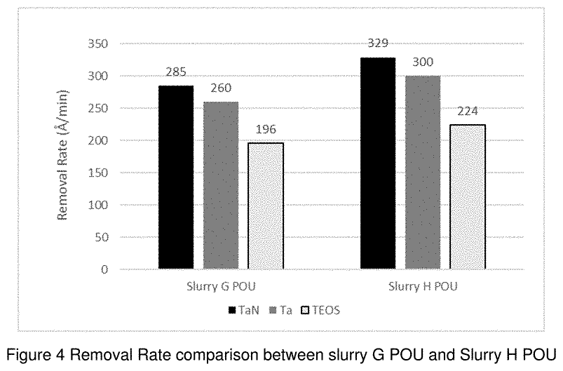

As shown in FIG. 4, both barrier (Ta and TaN) and ILD (TEOS) removal rate was boosted with addition of phosphonoacetic acid as rate booster slurry component.

Phosphonoacetic acid is a triprotic acid with PKa1 at 20° C. of 1.64.

Potassium nitrate is a rate booster in which K⁺ has molar ionic conductivity in aqueous solution at 25° C. of 73.5 S·cm²/mol and NO₃⁻ has molar ionic conductivity in aqueous solution at 25° C. of 71.46 S·cm²/mol.

Thus, Example 4 demonstrated that addition of a polyprotic acid with PKa1 between 1 and 3 can booster both barrier and ILD removal rate.

### Example 5

The chemical constituents used for the slurry were shown in Table 6. DI Water was added to make the composition 100 wt. %.

The PH of the slurry is 10-11.

TABLE 6

| Composition | | Slurry I | Slurry J |
|---|---|---|---|
| DI water | Solvent | 85.02 | 81.82 |
| Potassium oxalate | Chemical additive | | 0.50 |
| monohydrate | | | |
| Potassium Silicate | Chemical additive | 0 | 2.7 |
| Silica Particle | Abrasive | 14.9 | 14.9 |
| benzotriazole | Inhibitor | 0.0500 | 0.0500 |
| Surfactant (Dynol 607) | Surfactant | 0.03 | 0.03 |

The slurry was prepared with a normal slurry preparation process, that is, by adding each chemical constituent shown in Table 6 continuously at room temperature with a short break (several minutes) apart from each component.

The slurries at point of use (POU) for polishing were slurries G and H after diluting with DI water and adding 1 wt. % hydrogen peroxide as an oxidizing agent, as shown in Table 7.

TABLE 7

| | Slurry I | Slurry J |
|---|---|---|
| | POU | POU |
| DI water | 66 | 66 |
| Slurry I | 33 | |
| Slurry J | | 33 |
| hydrogen peroxide | 1 | 1 |

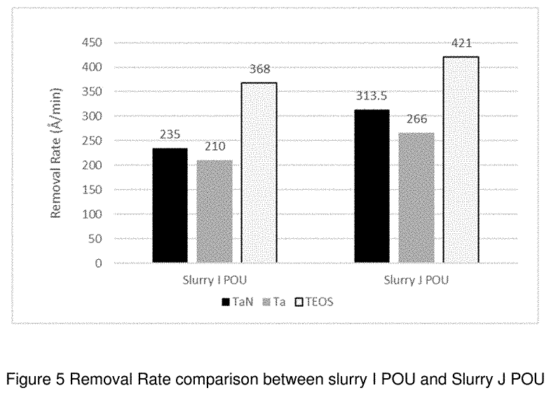

As shown in FIG. 5, both barrier (Ta and TaN) and ILD (TEOS) removal rates were boosted with the addition of both potassium oxalate and potassium silicate.

Potassium oxalate monohydrate is a salt of diprotic acid with PKa1 at 20° C. of 1.23.

Potassium silicate is the salt of silicic acid, and silicic acid is a polyprotic acid with PKa1 at 20° C. of 6-10.

Thus, Example 5 demonstrated that the addition of both a salt of polyprotic acid with PKa1 between 1 and 3 and a salt of polyprotic acid with PKa1 between 0.5 to 10 can boost both barrier and ILD removal rates.

### Example 6

The chemical constituents used for the slurry were shown in Table 8. DI Water was added to make the composition 100 wt. %.

The PH of the slurry is 9-11.

TABLE 8

| Composition | | Slurry E | Slurry K |
|---|---|---|---|
| DI water | Solvent | 94.97 | 93.87 |
| Phosphonacetic acid | Chemical additive | | 0.10 |
| Potassium Silicate | Chemical additive | 0 | 1 |
| Silica Particle | Abrasive | 5 | 5 |
| benzotriazole | Inhibitor | 0.0200 | 0.0200 |
| Surfactant (Dynol 607) | Surfactant | 0.01 | 0.01 |

The slurry was prepared with a normal slurry preparation process, that is, by adding each chemical constituent shown in Table 8 continuously at room temperature with a short break (several minutes) apart from each component.

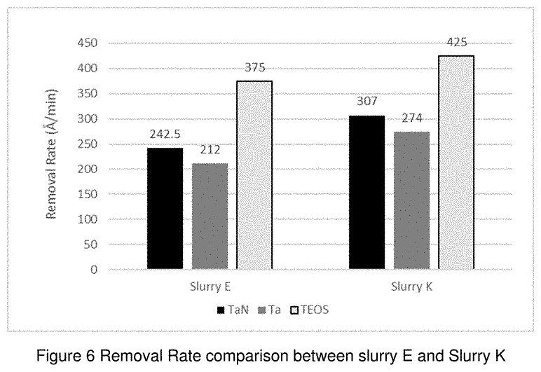

As shown in FIG. 6, both barrier (Ta and TaN) and ILD (TEOS) removal rates were boosted with the addition of both phosphonacetic and potassium silicate.

Phosphonacetic acid is a diprotic acid with PKa1 at 20° C. of 1.64.

Potassium silicate is the salt of silicic acid, and silicic acid is a polyprotic acid with PKa1 at 20° C. of 6-10.

Thus, Example 6 demonstrated that the addition of both a salt of polyprotic acid with PKa1 between 1 and 3 and a salt of polyprotic acid with PKa1 between 0.5 to 10 can boost both barrier and ILD removal rates.

### Example 7

The chemical constituents used for the slurry were shown in Table 9. DI Water was added to make the composition 100 wt. %.

The PH of the slurry is 7-11.

TABLE 9

| Composition | | Slurry I | Slurry L |
|---|---|---|---|
| DI water | Solvent | 85.02 | 81.92 |
| Phenylphosphonic acid | Chemical additive | | 0.40 |
| Potassium Silicate | Chemical additive | 0 | 2.7 |
| Silica Particle | Abrasive | 14.9 | 14.9 |
| benzotriazole | Inhibitor | 0.0500 | 0.0500 |
| Surfactant (Dynol 607) | Surfactant | 0.03 | 0.03 |

The slurry was prepared with a normal slurry preparation process, that is, by adding each chemical constituent shown in Table 9 continuously at room temperature with a short break (several minutes) apart from each component.

The slurries at point of use (POU) for polishing were slurries G and H after diluting with DI water and adding 1 wt. % hydrogen peroxide as an oxidizing agent, as shown in Table 7.

TABLE 10

| | Slurry I | Slurry |
|---|---|---|
| | POU | L POU |
| DI water | 66 | 66 |
| Slurry I | 33 | |
| Slurry L | | 33 |
| hydrogen peroxide | 1 | 1 |

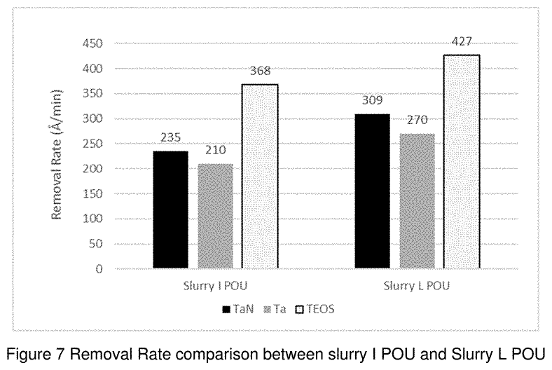

As shown in FIG. 7. both barrier (Ta and TaN) and ILD (TEOS) removal rates were boosted with the addition of both phenylphosphonic acid and potassium silicate.

Phenylphosphonic acid is a diprotic acid with PKa1 at 20° C. of 1.63.

Potassium silicate is the salt of silicic acid, and silicic acid is a polyprotic acid with PKa1 at 20° C. of 6-10.

Thus, Example 7 demonstrated that the addition of both a salt of polyprotic acid with PKa1 between 1 and 3 and a salt of polyprotic acid with PKa1 between 0.5 to 10 can boost both barrier and ILD removal rates.

### Example 8

The chemical constituents used for the slurry were shown in Table 11. DI Water was added to make the composition 100 wt. %.

The PH of the slurry is 7-11.

TABLE 11

| Composition | | Slurry M | Slurry N |
|---|---|---|---|
| DI water | Solvent | 84.82 | 83.02 |
| L-tartaric acid | Chemical additive | | 0.3 |
| Potassium hydroxide | PH adjusting agent | 0.2 | 0.2 |
| Potassium carbonate | Chemical additive | | 1.5 |
| Silica Particle | Abrasive | 14.9 | 14.9 |
| benzotriazole | Inhibitor | 0.05 | 0.05 |
| Surfactant (Dynol | Surfactant | 0.03 | 0.03 |
| 607) | | | |

The slurry was prepared with a normal slurry preparation process, that is, by adding each chemical constituent shown in Table 11 continuously at room temperature with a short break (several minutes) apart from each component.

The slurries at point of use (POU) for polishing were slurries G and H after diluting with DI water and adding 1 wt. % hydrogen peroxide as an oxidizing agent, as shown in Table 7.

TABLE 12

| | Slurry M | Slurry N |
|---|---|---|
| | POU | POU |
| DI water | 66 | 66 |
| Slurry M | 33 | |
| Slurry N | | 33 |
| hydrogen peroxide | 1 | 1 |

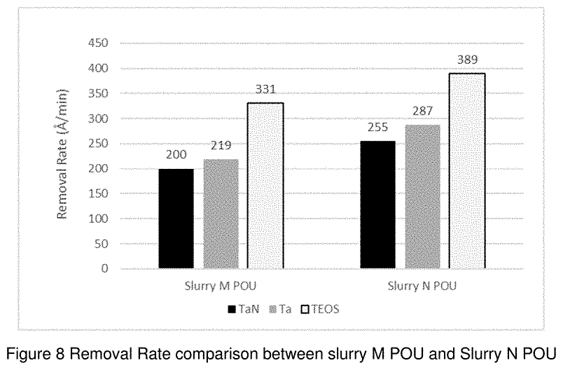

As shown in FIG. 8. both barrier (Ta and TaN) and ILD (TEOS) removal rates were boosted with the addition of both L-tartaric acid and potassium carbonate.

L-tartaric acid is a polyprotic acid with PKa1 at 20° C. of 2.82.

Potassium carbonate is a salt of diprotic acid with PKa1 at 20° C. of 6.3.

Thus, Example 8 demonstrated that the addition of both a salt of polyprotic acid with PKa1 between 1 and 3 and a salt of polyprotic acid with PKa1 between 1 to 7 can boost both barrier and ILD removal rates.

Working examples have demonstrated that the barrier layer slurry using chemical additive comprising diprotic acid, its derivatives and their salts; triprotic acid, its derivatives and their salts; and combinations thereof boosts barrier and ILD removal rates.

The foregoing examples and description of the embodiments should be taken as illustrating, rather than as limiting the present invention as defined by the claims. As will be readily appreciated, numerous variations and combinations of the features set forth above can be utilized without departing from the present invention as set forth in the claims. Such variations are intended to be included within the scope of the following claims.

1. A barrier chemical mechanical planarization polishing composition comprising:
≥2.4 wt. % of abrasive;
≤5 wt. % of chemical additive;
corrosion inhibitor,
water soluble solvent; and
optionally
second rate booster selected from the group consisting of nitrate salt and its derivatives;
nitric salt and its derivatives; chloride salt and its derivatives; and combinations thereof;
surfactant selected from the group consisting of a non-ionic surfactant, an anionic surfactant, a cationic surfactant, an ampholytic surfactant, and combinations thereof;
pH adjusting agent;
oxidizing agent;
chelator;
wherein
the chemical additive comprising at least one polyprotic acid or its salt having more than one Pka and having Pka1 from 0.5 to 10;
the water soluble solvent is selected from the group consisting of DI water, a polar solvent and a mixture of DI water and polar solvent; wherein the polar solvent is selected from the group consisting of alcohol, ether, ketone, or other polar reagent; and
the polishing composition has a pH of 4 to 12.

2. The barrier chemical mechanical planarization polishing composition of claim 1, wherein the abrasive is selected from the group consisting of high purity colloidal silica, nano-sized colloidal silica, alumina, ceria, germania, silica, titania, zirconia, alumina dopes colloidal silica in lattices, and combinations thereof; and the abrasive has a mean particle size of 10 nm to 300 nm.

3. The barrier chemical mechanical planarization polishing composition of claim 1, wherein the chemical additive is selected from the group consisting of phosphonoacetic acid, its derivatives and their salts; phosphonic acid, its derivatives and their salts; phenylphosphonic acid, its derivatives and their salts; molybdenum diacid, it derivatives and their salts; oxalic acid, its derivatives and their salts; sulfurous acid, its derivative and their salts; arsenic acid, its derivatives and their salts; nitrobenzoic acid, its derivative and their salts; malonic acid, its derivative and their salts; phthalic acid, its derivative and their salts; silicic acid, its derivative and their salts; carbonic acid, its derivative and their salts; and combinations thereof.

4. The barrier chemical mechanical planarization polishing composition of claim 1, wherein the corrosion inhibitor is selected from the group consisting of benzotriazole, 3-amino-1, 2, 4-triazole, 3, 5-diamine-1, 2, 4-triazole, and combinations thereof; and the corrosion inhibitor is present in an amount of from 0.005 wt. % to 0.5 wt. %.

5. The barrier chemical mechanical planarization polishing composition of claim 1, wherein the composition further comprises at least one of:
the surfactant selected from the group consisting of an acetylenic diol surfactant, an alcohol ethoxylate surfactant, and a combination thereof; and the surfactant is present in an amount of from 0.001 wt. % to 1.0 wt. %;
the second rate booster selected from the group consisting of nitrate salt and its derivatives; nitric salt and its derivatives; chloride salt and its derivatives; acetate salt and its derivatives; and combinations thereof; and the second rate booster is used in an amount ranging from 0.05 wt. % to 5 wt. %;
the pH adjusting agent selected from the group consisting of a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia,
tetraethylammonium hydroxide, ethylenediamine, piperazine, polyethyleneimine, modified polyethyleneimine, and combinations thereof to raise pH of the polishing composition; and the pH adjusting agent is used in an amount ranging from 0.001 wt. % to 1 wt. %;
the oxidizing agent selected from the group consisting of hydrogen peroxide, periodic acid, potassium iodate, potassium permanganate, ammonium persulfate, ammonium molybdate, ferric nitrate, nitric acid, potassium nitrate, ammonia, amine compounds, and combinations thereof; and the oxidizing agent is used in an amount ranging from about 0.05 wt. % to about 5.0 wt. %; and
the chelator selected from the group consisting of organic acids and their salts; polymeric acids and their salts; water-soluble copolymers and their salts; copolymers and their salts containing at least two different types of acid groups selected from carboxylic acid groups; sulfonic acid groups; phosphoric acids; and pyridine acids in the same molecule of a copolymer; polyvinyl acids and their salts; polyethylene oxide; polypropylene oxide; pyridine, pyridine derivatives, bipyridine, bipyridine derivatives, and combinations thereof; and the chelator is used in an amount ranging from 0.05 wt. % to about 5 wt. %.

6. The barrier chemical mechanical planarization polishing composition of claim 1, wherein the composition comprises silicon abrasive particles having a mean particle size of 15 nm to 200 nm; 0.025 wt. % to 4 wt. % of chemical additive selected from the group consisting of malonic acid, potassium sulfite, potassium molybdate, potassium silicate, potassium oxalate monohydrate, phosphonoacetic acid, and combinations thereof; an acetylenic diol surfactant or an alcohol ethoxylate surfactant; and water; wherein the composition has a pH of 6 to 11.

7. The barrier chemical mechanical planarization polishing composition of claim 1, wherein the composition comprises silicon abrasive particles having a mean particle size of 25 nm and 90 nm; 0.025 wt. % to 4 wt. % of chemical additive selected from the group consisting of malonic acid, potassium sulfite, potassium molybdate, potassium silicate, potassium oxalate monohydrate, phosphonoacetic acid, and combinations thereof; second rate booster selected from the group consisting of sodium silicate, ammonium silicate, tetramethylammonium silicate, tetrabutylammonium silicate, tetraethylammonium silicate, and combinations thereof; an acetylenic diol surfactant or an alcohol ethoxylate surfactant; and water; wherein the composition has a pH of 7 to 11.

8. The barrier chemical mechanical planarization polishing composition of claim 1, wherein the composition comprises silicon abrasive particles having a mean particle size of 25 nm and 90 nm; 0.025 wt. % to 4 wt. % of chemical additive having at least two selected from the group consisting of malonic acid, potassium sulfite, potassium molybdate, potassium silicate, potassium oxalate monohydrate, phosphonoacetic acid, and combinations thereof; second rate booster selected from the group consisting of sodium silicate, ammonium silicate, tetramethylammonium silicate, tetrabutylammonium silicate, tetraethylammonium silicate, and combinations thereof; an acetylenic diol surfactant or an alcohol ethoxylate surfactant; and water; wherein the composition has a pH of 7 to 11.

9. A polishing method for chemical mechanical planarization of a semiconductor device comprising at least one surface having at least a barrier layer and a dielectric layer; the method comprising the steps of:
providing the semiconductor device;
providing a polishing pad;
providing a polishing composition comprising;
≥2.4 wt. % of abrasive;
≤5 wt. % of chemical additive;
corrosion inhibitor,
water soluble solvent; and
optionally
second rate booster selected from the group consisting of nitrate salt and its derivatives; nitric salt and its derivatives; chloride salt and its derivatives; and
combinations thereof;
surfactant selected from the group consisting of a non-ionic surfactant, an anionic surfactant, a cationic surfactant, an ampholytic surfactant, and combinations thereof;
pH adjusting agent;
oxidizing agent;
chelator;
wherein
the chemical additive comprises at least one polyprotic acid and its salt having PKa1 from 0.5 to 10;
the water-soluble solvent is selected from the group consisting of DI water, a polar solvent and a mixture of DI water and polar solvent; wherein the polar solvent is selected from the group consisting of alcohol, ether, ketone, or other polar reagent; and
the composition has a pH of 4 to 12;
contacting the surface of the semiconductor substrate with the polishing pad and the chemical mechanical polishing composition; and
polishing the least one surface;
wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof.

10. The polishing method of claim 9, wherein the abrasive is selected from the group consisting of high purity colloidal silica, nano-sized colloidal silica, alumina, ceria, germania, silica, titania, zirconia, alumina dopes colloidal silica in lattices, and combinations thereof; and the abrasive has a mean particle size of 10 nm to 300 nm.

11. The polishing method of claim 9, wherein the chemical additive is selected from the group consisting of phosphonoacetic acid, its derivatives and their salts; phosphonic acid, its derivatives and their salts; phenylphosphonic acid, its derivatives and their salts; molybdenum diacid, it derivatives and their salts; oxalic acid, its derivatives and their salts; sulfurous acid, its derivative and their salts; arsenic acid, its derivatives and their salts; nitrobenzoic acid, its derivative and their salts; malonic acid, its derivative and their salts; phthalic acid, its derivative and their salts; silicic acid, its derivative and their salts; carbonic acid, its derivative and their salts; and combinations thereof.

12. The polishing method of claim 9, wherein the corrosion inhibitor is selected from the group consisting of benzotriazole, 3-amino-1, 2, 4-triazole, 3, 5-diamine-1, 2, 4-triazole, and combinations thereof; and the corrosion inhibitor is present in an amount of from 0.005 wt. % to 0.5 wt. %.

13. The polishing method of claim 9, wherein the polishing composition further comprises at least one of:
the surfactant selected from the group consisting of an acetylenic diol surfactant, an alcohol ethoxylate surfactant, and a combination thereof; and the surfactant is present in an amount of from 0.001 wt. % to 1.0 wt. %;
the second rate booster selected from the group consisting of nitrate salt and its derivatives; nitric salt and its derivatives; chloride salt and its derivatives; acetate salt and its derivatives; and combinations thereof; and the second rate booster is used in an amount ranging from 0.05 wt. % to 5 wt. %;
the pH adjusting agent selected from the group consisting of a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and the pH adjusting agent is used in an amount ranging from 0.001 wt. % to 1 wt. %;
the oxidizing agent selected from the group consisting of hydrogen peroxide, periodic acid, potassium iodate, potassium permanganate, ammonium persulfate, ammonium molybdate, ferric nitrate, nitric acid, potassium nitrate, ammonia, amine compounds, and combinations thereof; and the oxidizing agent is used in an amount ranging from about 0.05 wt. % to about 5.0 wt. %; and
the chelator selected from the group consisting of organic acids and their salts; polymeric acids and their salts; water-soluble copolymers and their salts; copolymers and their salts containing at least two different types of acid groups selected from carboxylic acid groups; sulfonic acid groups; phosphoric acids; and pyridine acids in the same molecule of a copolymer; polyvinyl acids and their salts; polyethylene oxide; polypropylene oxide; pyridine, pyridine derivatives, bipyridine, bipyridine derivatives, and combinations thereof; and the chelator is used in an amount ranging from 0.05 wt. % to about 5 wt. %.

14. The polishing method of claim 9, wherein the polishing composition comprises silicon abrasive particles having a mean particle size of 15 nm to 200 nm; 0.025 wt. % to 4 wt. % of chemical additive selected from the group consisting of malonic acid, potassium sulfite, potassium molybdate, potassium silicate, potassium oxalate monohydrate, phosphonoacetic acid, and combinations thereof; an acetylenic diol surfactant or an alcohol ethoxylate surfactant; water; the polishing composition has a pH of 6 to 11; and the at least one surface comprises tantalum and tantalum nitride, and silicon dioxide.

15. The polishing method of claim 9, wherein the polishing composition comprises silicon abrasive particles having a mean particle size of 25 nm and 90 nm; 0.025 wt. % to 4 wt. % of chemical additive selected from the group consisting of malonic acid, potassium sulfite, potassium molybdate, potassium silicate, potassium oxalate monohydrate, phosphonoacetic acid, and combinations thereof; second rate booster selected from the group consisting of sodium silicate, ammonium silicate, tetramethylammonium silicate, tetrabutylammonium silicate, tetraethylammonium silicate, and combinations thereof; an acetylenic diol surfactant or an alcohol ethoxylate surfactant; water; the polishing composition has a pH of 7 to 11; and the at least one surface comprises tantalum and tantalum nitride, and silicon dioxide.

16. The polishing method of claim 9, wherein the composition comprises silicon abrasive particles having a mean particle size of 25 nm and 90 nm; 0.025 wt. % to 4 wt. % of chemical additive having at least two selected from the group consisting of malonic acid, potassium sulfite, potassium molybdate, potassium silicate, potassium oxalate monohydrate, phosphonoacetic acid, and combinations thereof; second rate booster selected from the group consisting of sodium silicate, ammonium silicate, tetramethylammonium silicate, tetrabutylammonium silicate, tetraethylammonium silicate, and combinations thereof; an acetylenic diol surfactant or an alcohol ethoxylate surfactant; and water; wherein the composition has a pH of 7 to 11.

17. A system for chemical mechanical planarization, comprising:
a semiconductor device comprising at least one surface having at least a barrier layer and a dielectric layer;
a polishing pad; and
a polishing composition comprising
≥2.4 wt. % of abrasive;
≤5 wt. % of chemical additive comprising polyprotic acid and its salt having PKa1 from 0.5 to 10;
corrosion inhibitor,
water soluble solvent; and
optionally
second rate booster selected from the group consisting of nitrate salt and its derivatives; nitric salt and its derivatives; chloride salt and its derivatives; and
combinations thereof;
surfactant selected from the group consisting of a non-ionic surfactant, an anionic surfactant, a cationic surfactant, an ampholytic surfactant, and combinations thereof;
pH adjusting agent;
oxidizing agent;
chelator;
wherein
the water soluble solvent is selected from the group consisting of DI water, a polar solvent and a mixture of DI water and polar solvent; wherein the polar solvent is selected from the group consisting of alcohol, ether, ketone, or other polar reagent; and
the composition has a pH of 4 to 12
wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof; and
the at least one surface is in contact with the polishing pad and the polishing composition.

18. The system of claim 17, wherein the abrasive is selected from the group consisting of high purity colloidal silica, nano-sized colloidal silica, alumina, ceria, germania, silica, titania, zirconia, alumina dopes colloidal silica in lattices, and combinations thereof; and the abrasive has a mean particle size of 10 nm to 300 nm.

19. The system of claim 17, wherein the chemical additive is selected from the group consisting of phosphonoacetic acid, its derivatives and their salts; phosphonic acid, its derivatives and their salts; phenylphosphonic acid, its derivatives and their salts; molybdenum diacid, it derivatives and their salts; oxalic acid, its derivatives and their salts; sulfurous acid, its derivative and their salts; arsenic acid, its derivatives and their salts; nitrobenzoic acid, its derivative and their salts; malonic acid, its derivative and their salts; phthalic acid, its derivative and their salts; silicic acid, its derivative and their salts; carbonic acid, its derivative and their salts; and combinations thereof.

20. The system of claim 17, wherein the corrosion inhibitor is selected from the group consisting of benzotriazole, 3-amino-1, 2, 4-triazole, 3, 5-diamine-1, 2, 4-triazole, and combinations thereof; and the corrosion inhibitor is present in an amount of from 0.005 wt. % to 0.5 wt. %.

21. The system of claim 17, wherein the polishing composition further comprises at least one of:
the surfactant selected from the group consisting of an acetylenic diol surfactant, an alcohol ethoxylate surfactant, and a combination thereof; and the surfactant is present in an amount of from 0.001 wt. % to 1.0 wt. %;
the second rate booster selected from the group consisting of nitrate salt and its derivatives; nitric salt and its derivatives; chloride salt and its derivatives; acetate salt and its derivatives; and combinations thereof; and the second rate booster is used in an amount ranging from 0.05 wt. % to 5 wt. %;
the pH adjusting agent selected from the group consisting of a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and the pH adjusting agent is used in an amount ranging from 0.001 wt. % to 1 wt. %;
the oxidizing agent selected from the group consisting of hydrogen peroxide, periodic acid, potassium iodate, potassium permanganate, ammonium persulfate, ammonium molybdate, ferric nitrate, nitric acid, potassium nitrate, ammonia, amine compounds, and combinations thereof; and the oxidizing agent is used in an amount ranging from about 0.05 wt. % to about 5.0 wt. %; and
the chelator selected from the group consisting of organic acids and their salts; polymeric acids and their salts; water-soluble copolymers and their salts; copolymers and their salts containing at least two different types of acid groups selected from carboxylic acid groups; sulfonic acid groups; phosphoric acids; and pyridine acids in the same molecule of a copolymer; polyvinyl acids and their salts; polyethylene oxide; polypropylene oxide; pyridine, pyridine derivatives, bipyridine, bipyridine derivatives, and combinations thereof; and the chelator is used in an amount ranging from 0.05 wt. % to about 5 wt. %.

22. The system of claim 17, wherein the polishing composition comprises silicon abrasive particles having a mean particle size of 15 nm to 200 nm; 0.025 wt. % to 4 wt. % of chemical additive selected from the group consisting of malonic acid, potassium sulfite, potassium molybdate, potassium silicate, potassium oxalate monohydrate, phosphonoacetic acid, and combinations thereof; an acetylenic diol surfactant or an alcohol ethoxylate surfactant; water; the polishing composition has a pH of 6 to 11; and the at least one surface comprises tantalum and tantalum nitride, and silicon dioxide.

23. The system of claim 17, wherein the polishing composition comprises silicon abrasive particles having a mean particle size of 25 nm and 90 nm; 0.025 wt. % to 4 wt. % of chemical additive selected from the group consisting of malonic acid, potassium sulfite, potassium molybdate, potassium silicate, potassium oxalate monohydrate, phosphonoacetic acid, and combinations thereof; second rate booster selected from the group consisting of sodium silicate, ammonium silicate, tetramethylammonium silicate, tetrabutylammonium silicate, tetraethylammonium silicate, and combinations thereof; an acetylenic diol surfactant or an alcohol ethoxylate surfactant; water; the polishing composition has a pH of 7 to 11; and the at least one surface comprises tantalum and tantalum nitride, and silicon dioxide.

24. The system of claim 17, wherein the composition comprises silicon abrasive particles having a mean particle size of 25 nm and 90 nm; 0.025 wt. % to 4 wt. % of chemical additive having at least two selected from the group consisting of malonic acid, potassium sulfite, potassium molybdate, potassium silicate, potassium oxalate monohydrate, phosphonoacetic acid, and combinations thereof; second rate booster selected from the group consisting of sodium silicate, ammonium silicate, tetramethylammonium silicate, tetrabutylammonium silicate, tetraethylammonium silicate, and combinations thereof; an acetylenic diol surfactant or an alcohol ethoxylate surfactant; and water; wherein the composition has a pH of 7 to 11.
